(19) United States
(12) Patent Application Publication
(10) Pub. No.: US 2024/0272922 A1
(43) Pub. Date: Aug. 15, 2024

(54) SIMULATION FOR SCHEDULERS ASSOCIATED WITH AUTONOMOUS VEHICLE SOFTWARE BUILDS

(71) Applicant: GM Cruise Holdings LLC, San Francisco, CA (US)

(72) Inventors: Jinju Lu, San Mateo, CA (US); Mahaaveer Prabu Jayabalan, San Jose, CA (US); Ju Bing Chen, San Jose, CA (US)

(73) Assignee: GM Cruise Holdings LLC, San Francisco, CA (US)

(21) Appl. No.: 18/167,189

(22) Filed: Feb. 10, 2023

(51) Int. Cl. G06F 9/455; G06F 9/48; G06F 11/30; G06F 11/34

(52) U.S. Cl. CPC G06F 9/455; G06F 9/4881; G06F 11/3013; G06F 11/3423

(57) ABSTRACT

Systems and methods for evaluating schedulers that schedule jobs(s) and/or tasks(s) related to vehicle software builds and/or vehicle simulations are provided. A computer-implemented system, including one or more processing units; and one or more non-transitory computer-readable media storing instructions, when executed by the one or more processing units, cause the one or more processing units to perform operations including receiving a configuration including a simulated request for executing a task associated with at least one of a vehicle software build or a vehicle simulation of a vehicle; executing a simulation of operations of a scheduler and task execution, wherein the executing includes determining, by the scheduler, a schedule for executing the task based on the configuration and at least one of a driving scenario or a vehicle compute framework associated with the task; and calculating a metric for the scheduler based on an output of the simulation.

### BACKGROUND

### 1. Technical Field

The present disclosure generally relates to autonomous vehicles and, more specifically, to simulation for schedulers associated with autonomous vehicle software.

### 2. Introduction

Autonomous vehicles, also known as self-driving cars, driverless vehicles, and robotic vehicles, may be vehicles that use multiple sensors to sense the environment and move without human input. Automation technology in the autonomous vehicles may enable the vehicles to drive on roadways and to accurately and quickly perceive the vehicle's environment, including obstacles, signs, and traffic lights. Autonomous technology may utilize map data that can include geographical information and semantic objects (such as parking spots, lane boundaries, intersections, crosswalks, stop signs, traffic lights) for facilitating the vehicles in making driving decisions. The vehicles can be used to pick up passengers and drive the passengers to selected destinations. The vehicles can also be used to pick up packages and/or other goods and deliver the packages and/or goods to selected destination.

### BRIEF DESCRIPTION OF THE DRAWINGS

The various advantages and features of the present technology will become apparent by reference to specific implementations illustrated in the appended drawings. A person of ordinary skill in the art will understand that these drawings show only some examples of the present technology and would not limit the scope of the present technology to these examples. Furthermore, the skilled artisan will appreciate the principles of the present technology as described and explained with additional specificity and detail through the use of the accompanying drawings in which:

FIG. 1 is a block diagram illustrating an infrastructure framework for autonomous vehicle (AV) software builds and/or AV simulations, according to embodiments of the present disclosure;

FIG. 2 is a block diagram illustrating an exemplary distributed resource pool configuration for AV software builds and/or AV simulations, according to embodiments of the present disclosure;

FIG. 3 illustrates an exemplary scheduling scheme for AV software builds and/or AV simulations, according to some embodiments of the present disclosure;

FIG. 4 illustrates an exemplary simulation scheme for evaluating a scheduler for AV software builds and/or AV simulations, according to some embodiments of the present disclosure;

FIG. 5 illustrates an exemplary simulation configuration for evaluating a scheduler for AV software builds and/or AV simulations, according to some embodiments of the present disclosure;

FIG. 6 is a flow diagram illustrating an exemplary scheduler simulation process, according to some embodiments of the present disclosure;

FIG. 7 illustrates an example system environment that may be used to facilitate AV dispatch and operations, according to some aspects of the disclosed technology; and

FIG. 8 illustrates an example processor-based system with which some aspects of the subject technology may be implemented.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form to avoid obscuring the concepts of the subject technology.

Autonomous vehicles (AVs) can provide many benefits. For instance, AVs may have the potential to transform urban living by offering opportunities for efficient, accessible and affordable transportation. An AV may be equipped with various sensors to sense an environment surrounding the AV and collect information (e.g., sensor data) to assist the AV in making driving decisions. To that end, the collected information or sensor data may be processed and analyzed to determine a perception of the AV's surroundings, extract information related to navigation, and predict future motions of the AV and/or other traveling agents in the AV's vicinity. The predictions may be used to plan a path for the AV (e.g., from a starting position to a destination). As part of planning, the AV may access map information and localize itself based on location information (e.g., from location sensors) and the map information. Subsequently, instructions can be sent to a controller to control the AV (e.g., for steering, accelerating, decelerating, braking, etc.) according to the planned path.

The operations of perception, prediction, planning, and control of an AV may be implemented using a combination of hardware and software components. For instance, an AV stack or AV compute process performing the perception, prediction, planning, and control may be implemented using one or more of software code and/or firmware code. However, in some embodiments, the software code and firmware code may be supplemented with hardware logic structures to implement the AV stack and/or AV compute process. The AV stack or AV compute process (the software and/or firmware code) may be executed on processor(s) (e.g., general-purpose processors, central processing units (CPUs), graphical processing units (GPUs), digital signal processors (DSPs), application specific integrated circuits (ASICs), etc.) and/or any other hardware processing components on the AV. Additionally, the AV stack or AV compute process may communicate with various hardware components (e.g., onboard sensors and control systems of the AV) and/or with an AV infrastructure over a network.

Training and testing AVs in the physical world can be challenging. For instance, to provide good testing coverage, an AV may be trained and tested to respond to various driving scenarios (e.g., millions of physical road test scenarios) before it can be deployed in an unattended real-life roadway system. As such, it may be costly and time-consuming to train and test AVs on physical roads. Furthermore, there may be test cases that are difficult to create or too dangerous to cover in the physical world. Accordingly, it may be desirable to train and validate AVs in a simulation environment, covering at least a majority of the test scenarios. In this way, the number of physical road tests can be reduced while still providing good test coverage. Further, autonomous driving algorithms can be developed, fine-tuned, and tested with a shorter turn-around time on a simulation platform than it would have been with physical road tests

A simulator may simulate (or mimic) real-world conditions (e.g., roads, lanes, buildings, obstacles, other traffic participants, trees, lighting conditions, weather conditions, etc.) so that the AV stack and/or AV compute process of an AV may be tested in a virtual environment that is close to a real physical world. Testing AVs in a simulator can be more efficient and allow for creation of specific traffic scenarios. To that end, the AV compute process implementing the perception, prediction, planning, and control algorithms can be developed, validated, and fine-tuned in a simulation environment. More specifically, the AV compute process may be executed in an AV simulator (simulating various traffic scenarios), and the AV simulator may compute metrics related to AV driving decisions, AV response time, etc. to determine the performance of an AV to be deployed with the AV compute process.

While AV simulation can allow for validation of AV behaviors with newly developed autonomous driving algorithms across a large number of driving scenarios before deploying those algorithms in a real-life roadway system, providing an infrastructure that can support a large number of AV simulation runs on a daily basis can be challenging. Further, an infrastructure platform may be used not only to provision for AV simulation runs, but also for various stages of AV software development and release integration. For instance, after an algorithm is validated through simulation, the validated algorithm may be integrated and compiled into an AV software build (e.g., a certain version of software or firmware). In software development, a build is a process of compiling (or converting) software program source codes into an image (e.g., a binary image) that can be executed by a computer-implemented system. The integrated software build may be further tested. For instance, a set of test cases covering various driving scenarios may be defined and the integrated AV software build may be tested against these test cases. After successfully testing the integrated AV software build, the integrated AV software build may be compiled into an AV software release and the AV software release may be further tested (e.g., against the same set of test cases or a different or more extensive set of test cases) before the AV software release is deployed in AVs for real-road testing and real-road driving. As such, the number of AV simulations and/or AV software builds that run on the infrastructure platform may reach hundreds of thousands per day. Furthermore, the number of AV simulations and/or AV software builds may continue to grow as more driving scenarios are identified and/or generated and/or more advanced algorithms are being developed, released, and deployed.

In some examples, an infrastructure platform may be built on top of a cloud platform that provides various resources, such as compute resources (e.g., CPU cores and GPU cores), memory resources, storage resources, and/or network resources, for running AV simulations and/or AV software builds. In an example, the cloud platform may include a shared pool of configurable resources and may present its resources to a cloud user (e.g., the infrastructure platform) in the form of workers or virtual machines. To that end, a worker may be configured with a specific computational capacity (e.g., 12 CPU cores and 12 GPU core, 12 CPU cores with no GPU core, etc.), a specific storage capacity (e.g., 128 gigabytes (GB) of disk storage, 256 GB of disk storage, etc.), a specific memory capacity (e.g., 16 GB of random-access memory (RAM), 32 GB of RAM, etc.), and/or a specific network capacity (e.g., an uplink bandwidth or throughput and/or a downlink bandwidth or throughput). The cloud platform may be provided by a third-party provider, and each unit of resources or each worker may have an associated cost.

To support a large number of AV simulations and/or software builds on the infrastructure platform, it may be desirable to have an efficient scheduler to schedule these AV simulations and/or software builds (e.g., meeting job deadlines, optimizing resource utilization, and minimizing cost) on the cloud resources. To schedule workloads, a scheduler may consider a variety of factors, for example, including but not limited to a queue state, a task priority, a task deadline, a resource availability, a driving scenario (or use case), and/or a vehicle compute framework. A driving scenario may define roads in a certain city under a certain weather condition and/or having certain objects (e.g., traffic participants, buildings, and/or roadside objects) in the surrounding. AV software may generally include, but are not limited to a perception compute framework for determining a perception of an AV surroundings, a prediction compute framework for predicting a future motion of the AV or a traffic participant, a planning compute framework for planning a driving path for the AV, a replay framework for replaying a driving scenario, for example, based on driving logs captured from driving in a real-world roadways. There is currently no easy way to understand how the various scheduling factors may change the behaviors and/or decisions of the scheduler and/or its interactions with (or usages of) infrastructure resources.

Accordingly, the present disclosure provides techniques to generate a simulation engine that can evaluate and/or reliably predict outcomes (or scheduling decisions) of a scheduler and provide a better understanding of these decisions, for example, by mutating the various scheduling factors discussed above. A simulation engine (or simply a simulation) and/or a simulation model are specialized software programs used to simulate a real-world scenario (e.g., a scheduling scenario). In an aspect of the present disclosure, a computer-implemented system may implement a simulation for evaluating the performance of a scheduler that schedules AV jobs and/or tasks (related to AV software builds and/or AV simulations) on resources (e.g., infrastructure or cloud resources). A job may generally include a list of one or more tasks. Scheduling a job or task on a resource may refer to the assignment or allocation of resource(s) for executing the job or task and the ordering and/or preemption of job(s) and/or task(s) for the execution. The computer-implemented system may include one or more processing units and one or more non-transitory computer-readable media storing instructions, when executed by the one or more processing units, cause the one or more processing units to perform various scheduler and/or task execution simulation operations.

For instance, the computer-implemented system may receive a configuration. The configuration may include various parameters for configuring a simulation (e.g., a scheduling simulation) that simulates operations of a scheduler and task execution. In an example, the configuration may include at least a simulated request requesting execution of a task associated with at least one of a vehicle simulation (e.g., simulating operations of an AV, such as perception, prediction, planning, and/or control, for determining driving decision(s)) or a vehicle software build (e.g., compilation of an AV software stack or program codes for continuous integration including development, integration, and/or release). The computer-implemented system may execute the scheduling simulation based on the configuration. As part of executing the scheduling simulation, the computer-implemented system may determine, using the scheduler, a schedule for running the task based on the received configuration and at least one of a driving scenario or a vehicle compute framework associated with the task.

Different driving scenarios and/or different vehicle compute frameworks may vary the amount of time (task runtime) it takes to execute the task. Thus, in some aspects, the scheduler may estimate a runtime for the task based on the driving scenario and/or the vehicle compute framework associated with the requested task and may determine the schedule based on the estimated task runtime. In some aspects, the computer-implemented system may determine the schedule further based on a task category of the task. For instance, if the task (specified in the configuration) is for the vehicle simulation, the task may be categorized as a first task category. Alternatively, if the task (specified in the configuration) is for the vehicle software build, the task may be categorized as a second task category different than the first task category. In some examples, the scheduler may consider the second task category (associated with AV software releases) having a higher priority than the first task category (associated with AV simulations). Accordingly, the computer-implemented system may prioritize a task of the second task category over another task of the first task category.

As part of executing the scheduling simulation, the computer-implemented system may further perform the task execution based on the determined schedule using a task run model. The task run model may simulate the task execution without actually running the task on any real (or physical) hardware resources (e.g., infrastructure resources). In an example, the task run model may simulate a task runtime using a timer with simulated timer ticks (e.g., an actual time duration of 1 second can be mapped to a simulation time duration of 1 millisecond). In this way, the simulation can be sped up. That is, a task can be executed in the simulation faster than when it is executed in real time on real resources. The computer-implemented system may further calculate a metric for the scheduler based on one or more outputs of the simulation. In some examples, the metric can be a binary score with an indication of a pass or fail. In other examples, the metric can be a numerical score.

In some aspects, the computer-implemented system may determine the schedule further based on a queue state model and/or a resource availability model. The queue state model may model various queues and associated queueing of tasks. The resource availability model may simulate hardware resources (e.g., CPUs, GPUs, storage resources, memory resources, and/or network resources) and corresponding availabilities for the task execution.

In some aspects, the configuration may further include a variety of configuration parameters for the simulation. For instance, the configuration may further include an indication of at least one of a queue size or a number of pending tasks associated with (or to be modeled by) the queue state model. Additionally or alternatively, the configuration may include an indication of at least one of a compute resource capacity (e.g., a number of CPU cores and/or a number of GPU cores), a storage resource capacity (e.g., an amount of static memory or a RAM size), or a network resource capacity (e.g., an uploading throughput and/or a downloading throughout) for a hardware platform associated with (or modeled by) the resource availability model. Additionally or alternatively, the configuration may include an indication of at least one of a compute resource occupancy, a storage resource capacity occupancy, or a network resource occupancy for a hardware platform associated with (or to be modeled by) the resource availability model. Additionally or alternatively, the configuration may include an indication of at least one of a task priority, a task runtime, a task completion goal, a file downloading time duration (e.g., for downloading road assets and/or driving scenario files), or a file uploading time duration (e.g., for uploading an AV driven path or AV decision(s)) associated with the task.

In some aspects, the computer-implemented system may define or configure a variety of assertion rules (e.g., predefined conditions) to determine whether the scheduler performance meets certain conditions. For instance, as part of executing the scheduling simulation, the computer-implemented system may validate at least one of a task start time, a task runtime, a task completion time, a task preemption, a task execution order, or a queue state from the execution of the scheduling simulation against a predefined condition.

In some aspects, the computer-implemented system may calculate the metric for the scheduler based on a comparison between a completion time of the task and a completion goal for the task. Additionally or alternatively, the computer-implemented system may calculate the metric for the scheduler based on an ordering of tasks scheduled by the scheduler. Additionally or alternatively, the computer-implemented system may calculate the metric for the scheduler based on priorities of tasks executed over a certain time duration.

The systems, schemes, and mechanisms described herein can advantageously enable evaluation of a scheduler for infrastructure resources by mutating various scheduling factors. Having a better understanding of scheduling decisions of a scheduler may allow for optimization of the scheduler so that resource utilization and/or task execution efficiency can be improved and infrastructure cost can be reduced. While the present disclosure may discuss scheduling in the context of task scheduling in some embodiments, similar scheduling mechanisms may be applied to job scheduling. Further, the term “software build” may generally refer to an AV compute process (e.g., for perception, prediction, planning, and/or control operations) that can be executed on any suitable processors and/or hardware accelerators. In some examples, a software build can also be referred to as a firmware build.

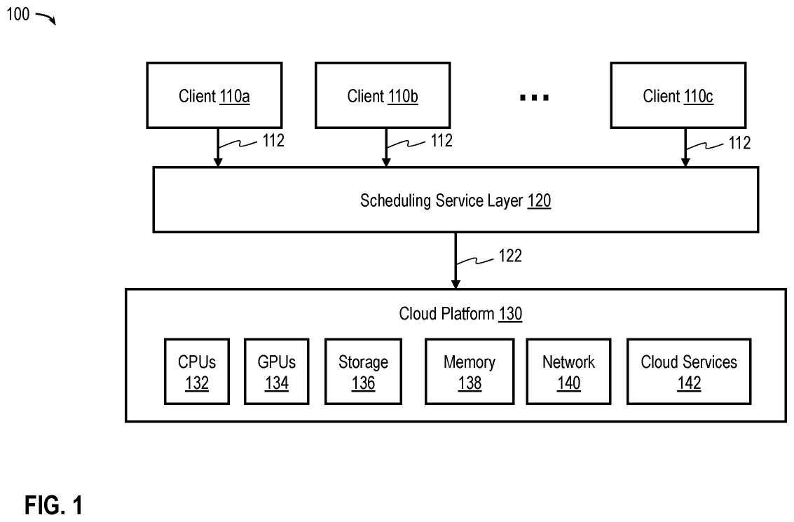

FIG. 1 is a block diagram illustrating an infrastructure framework 100 for AV software build(s) and/or AV simulation(s), according to some embodiments of the present disclosure. The infrastructure framework 100 may include a plurality of clients 110 (shown as 110a, 110b, . . . , 110c), a scheduling service layer 120, and a cloud platform 130. The cloud platform 130 may include a shared pool of configurable resources including CPU cores 132, GPU cores 134, storage resources 136 (e.g., disk space), memory 138 (e.g., RAMs), and/or network resources 140 (e.g., an uplink bandwidth, a downlink bandwidth, an uplink throughput, and/or a downlink throughput). The cloud platform 130 may also provide various cloud services 142 (e.g., databases hosting services, monitoring services, reporting services, query services, and/or container registry services, etc.) to assist scheduling and/or resource management. In some aspects, a provider of the cloud platform 130 may host the various resources and/or services at network data centers that are distributed in various geographical locations (e.g., at a west region of United States, an east region of United States, etc.). At a high level, the plurality of clients 110 (or client applications) may request the scheduling service layer 120 to execute certain AV simulation and/or software build jobs, and in response, the scheduling service layer 120 may schedule resources on the cloud platform 130 for execution of the requested jobs. Stated differently, the scheduling service layer 120 may operate as an abstraction layer to hide the underlying cloud platform 130 from the clients 110 so that the cloud platform 130 may be transparent to the clients 110.

The plurality of clients 110 may include AV simulation developers, AV software engineers, AV release and/or quality assurance (QA) engineers, etc. The clients 110 may submit job requests 112 to the scheduling service layer 120, for example, via scheduling service application interface (API) calls. Each job may include a collection of one or more tasks associated with an AV simulation or an AV software build (e.g., including implementation of sensing algorithms, machine learning (ML) models to identify objects in a driving scenario, ML models to facilitate autonomous driving, etc.). For instance, an AV simulation developer may submit a job for an AV simulation, an AV software engineer may submit a job for an AV software build under development or integration, and an AV release and/or QA engineer may submit a job for an AV software build in preparation for a release. In some aspects, the job request 112 may include a task specification specifying information (e.g., file information for AV driving scenario data or models, file information for processed AV artifacts for executing each task and/or an associated job completion deadline).

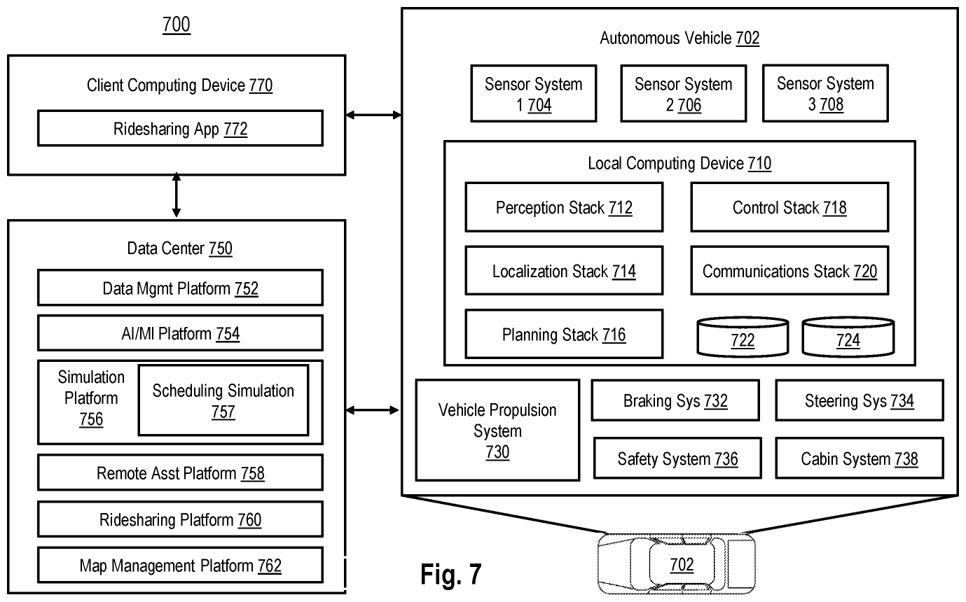

An AV simulation job may include various tasks related to execution of various AV simulations and/or analysis of the simulation outputs. An AV software build job may include compilation of various AV software and/or firmware builds, associated testing, and/or generation of software and/or firmware release packages (e.g., to be deployed in AVs similar to the AV 702 shown in FIG. 7). As an example, a task may run a simulation that performs object identification in a certain driving scenario using an ML model. As another example, a task may run a simulation that simulates a certain sensor system and performs a certain sensing algorithm using the sensor system. As yet another example, a task may run an AV code (e.g., firmware or software) implemented based on a certain AV simulation. As yet another example, a task may compile a certain AV software or firmware build and run the compiled code over certain driving test scenarios. In general, a task may be associated with any stages within an AV code release life cycle (from simulation to code release). In some aspects, tasks within a job can be dependent on one another. As an example, an AV simulation job may include a first task to execute a simulation that simulates a certain sensor algorithm and/or system and generates sensor data using the sensor algorithm and/or system, and a second task to execute a simulation that performs object identification from sensor data generated from the first task. As another example, an AV code release job may include a first task to compile source codes of a certain software or firmware and a plurality of tasks to test the software or firmware under various driving scenarios. In general, a job may include a list of one or more tasks to execute an AV simulation (e.g., executing software associated perception, prediction, planning, and/or control for determining driving decision(s)) or to build certain AV software codes related to AV perception, prediction, planning, and/or control (e.g., for a release).

The cloud platform 130 may present its resources (e.g., the CPU cores 132, GPU cores 134, the storage resources 136, and/or memory 138) to the scheduling service layer 120 in the form of workers or worker instances. As an example, a worker may include 12 CPU cores 132, 4 GPU cores 134, 350 GB of storage resources 136 (e.g., disk space), and 64 GB of memory 138. As another example, a worker may include 4 CPU cores 132, 100 GB of storage resources 136, 32 GB of memory 138, and no GPU cores 134. In general, the cloud platform 130 may provision for any suitable number of workers with any suitable configuration or combination of resources.

Upon receiving a job request 112 from a client 110, the scheduling service layer 120 may schedule resources (e.g., workers) on the cloud platform 130 to execute task(s) requested by the job request 112. The scheduling service layer 120 may utilize any suitable scheduling schemes. Some example scheduling schemes may include, but are not limited to, a first-in-first-out (FIFO) scheduling scheme, a completion time-driven scheme, or a gang scheduling scheme. A FIFO scheduling scheme may schedule tasks in the order as they are submitted or requested. A completion time-driven scheme may schedule a task that has an earlier completion deadline over a task that has a later completion deadline and may guarantee that a task will be completed by the requested completion deadline. A gang scheduling scheme may schedule related tasks to run simultaneously on different resources (or processors). Subsequently, the scheduling service layer 120 may transmit a request 122 to the cloud platform 130 to schedule available worker(s) or launch (“spin up”) additional worker(s) to execute the tasks, for example, via remote procedure calls (RPCs). In some aspects, the scheduling service layer 120 may spin up a worker by executing a virtual machine (VM) image on the cloud platform 130, and then download a separate binary task image (e.g., an executable image) to the worker for execution. In any case, the scheduling service layer 120 may be responsible for creating VM images (including scheduling within the VM), requesting the cloud platform 130 to launch or spin up certain workers, and assigning AV simulation and/or software build jobs to the workers. While not shown, in some aspects, the scheduling service layer 120 may also utilize or access map services to facilitate the execution of an AV simulation or software build job.

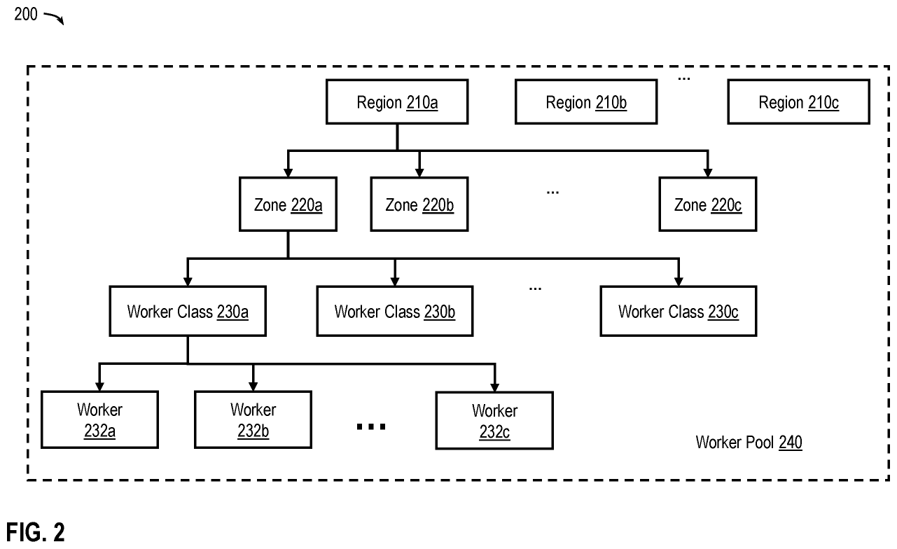

FIG. 2 is a block diagram illustrating an exemplary distributed worker pool configuration 200 for AV software builds and/or AV simulations, according to some embodiments of the present disclosure. In an example, the cloud platform 130 of FIG. 1 may include a worker pool similar to the worker pool 240 shown in the FIG. 2 to provide the CPU cores 132, GPU cores 134, the storage resources 136, the memory 138, the network resources 140, etc. for task execution. The worker pool 240 may be a shared pool of configurable resources distributed across multiple geographical locations. As shown, the worker pool 240 may include resources located at a plurality of regions 210 (shown as 210a, 210b, . . . , 210c). Some example regions 210 may include a region in Western United States, a region in Eastern United States, etc. Each region 210 may be partitioned into a plurality of zones or areas. In some instances, the different zones may correspond to different network data centers. For simplicity, FIG. 2 only illustrates zones 220 (shown as 220a, 220b, . . . , 220c) in the region 210a.

Each zone 220 may provision for various worker classes 230. A worker class 230 may be a template or a configuration of resource capacities. Different worker classes 230 may have different configurations for computational capacities, storage capacities, memory capacities, and/or network capacities. For instance, one worker class 230 may include a configuration for 12 CPU cores (e.g., the CPU cores 132), 4 GPU cores (e.g., the GPU cores 134), 350 GB of disk space (e.g., the storage resources 136), and 64 GB of memory (e.g., the memory 138), and another worker class 330 may include 4 CPU cores, 100 GB of storage resources, 32 GB of memory, and no GPU cores. In general, a zone 220 may provision for any suitable number of worker classes 330 with a configuration for any suitable combination of resources. For simplicity, FIG. 2 only illustrates worker classes 230 (shown as 230a, 230b, . . . , 230c) in the zone 220a.

Each worker class 230 may be instantiated into one or more worker instances or workers 232 (e.g., 1, 2, 3, 4, 5, 10, 20, 40, 100 or more). A worker 232 instantiated from a worker class 230 may have the resource capacities (for compute, storage, memory, and/or networking) as specified by the worker class 230. For simplicity, FIG. 2 only illustrates workers 232 (shown as 232a, 232b, . . . , 232c) of the worker class 230a.

In some aspects, the worker pool 240 may provision for various types of workers, for example, including non-preemptible workers 232 (or “standard workers”) and preemptible workers 232 of any suitable worker classes 230. The non-preemptible workers 232 may include committed workers that are already purchased at a certain cost, for example, by an organization that utilizes the worker pool 240. The non-preemptible workers 232 can also include workers that can be launched (or “spin up”) on-demand at a small additional cost. Once a non-preemptible worker 232 is launched, the non-preemptible worker 232 can be used by the infrastructure platform for as long as the infrastructure platform desires. On the other hand, a preemptible worker 232 may be requested (or “spin up”) on-demand with a lower cost than the on-demand preemptible workers 232 but can be preempted (or taken away) at some time point of time. As such, while a preemptible worker 232 may have a lower cost, a task scheduled on a preemptible worker may have the risk of not running to completion and having to be rerun on another worker 232.

In general, a scheduler may have various resource options for assigning resources for task execution and it is important for a scheduler (e.g., the scheduling service layer 120) to be able to schedule resources efficiently.

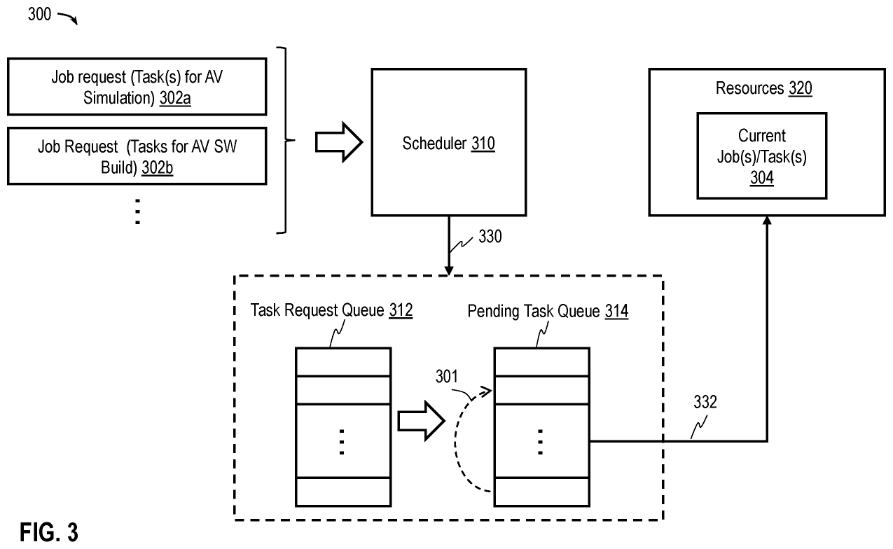

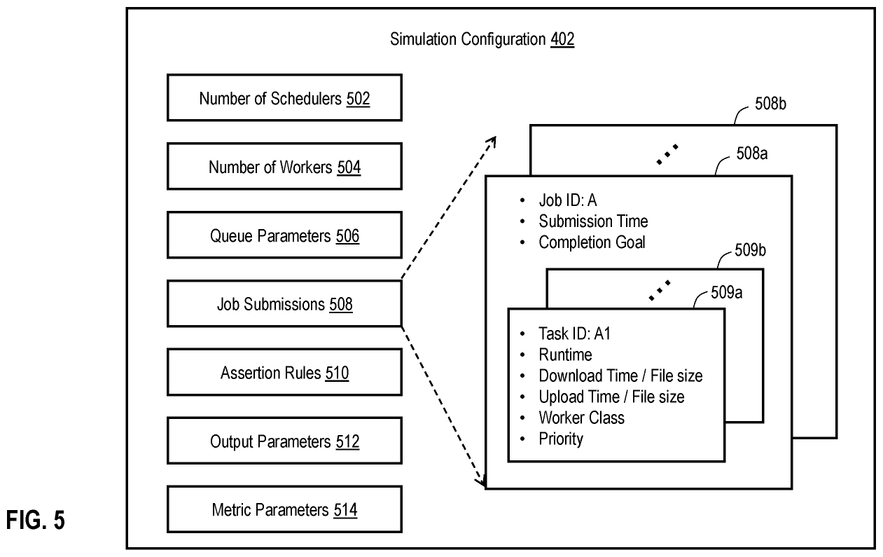

FIG. 3 illustrates an exemplary scheduling scheme 300 for AV software builds and/or AV simulations, according to some embodiments of the present disclosure. In an example, the scheduling service layer 120 of FIG. 1 may perform scheduling as shown in the scheduling scheme 300. As shown in FIG. 3, a scheduler 310 may receive a plurality of job requests 302 (individually shown as 302a and 302b). The job request 302 may be similar to the job request 112. Each job request 302 can include a list of one or more tasks. A task may be related to an AV software build (e.g., for development, integration, and/or release) or an AV simulation (e.g., simulating perception, prediction, planning, and/or control operations of an AV). In the illustrated example of FIG. 3, the job request 302a may include task(s) related to an AV simulation while the job request 302b may include task(s) related to an AV software build. In some instances, each job request 302 may include a task specification for each of its task as discussed above with reference to FIG. 1 and further below with reference to FIG. 5.

The scheduler 310 may schedule various tasks to be executed using resources 320. The resources 320 may include CPUs, GPUs, storage resources, memory resources, and/or network resources. In some examples, the resources 320 may be on a cloud platform similar to the cloud platform 130 of FIG. 1. In some examples, the resources 320 may be part of a worker pool similar to the worker pool 240 of FIG. 2.

To assist scheduling, the scheduler 310 may include various queues to queue pending jobs ready for execution. The scheduler 310 may generally use any suitable scheduling algorithms and/or any suitable queue structures with any suitable number of queues and corresponding queue sizes. In the illustrated example of FIG. 3, the scheduler 310 may have a task request queue 312 and a pending task queue 314. The task request queue 312 may queue or store jobs (and associated tasks) to be scheduled. The pending task queue 314 may queue or store jobs (and associated tasks) that are scheduled and pending to be executed. In an example, at 330, upon receiving the job request 302a, the scheduler 310 may queue tasks related to the job request 302a at the task request queue 312. Subsequently, the scheduler 310 may retrieve tasks related to the job request 302a from the task request queue 312, analyze the requirements (e.g., task priority, task deadline, estimated runtime, resources, downloading and/or uploading file sizes, etc.) for executing those tasks, and determine a schedule for executing those tasks based on the analysis. A schedule may include a task start time for each task, an order of task executions, resource(s) scheduled for each task execution.

As part of determining the schedule, the scheduler 310 may estimate a runtime for each task (e.g., based on the respective task specification) and assign or schedule resources from the resources 320 to run each task. That is, the scheduler 310 may map each task to certain resources (e.g., worker(s) 232) in the resources 320. To assign resources, the scheduler 310 may determine a suitable worker class (e.g., the worker class 230) for the executing the job, for example, by matching resource requirements for performing the job to resource availabilities of a worker class 230. In an example, when the resources 320 are configured as discussed above with reference to FIG. 2, the scheduler 310 may search for an available worker of the matched worker class. Alternatively, the scheduler 310 may request for (or “spin up”) a new worker instantiated from the matched worker class. The instantiation of a worker from a worker class may refer to launching a worker (or creating a VM) using a binary image having a resource configuration as specified by the corresponding worker class.

After determining the schedule for those tasks, the scheduler 310 may queue those tasks at the pending task queue 314 (e.g., in the order of execution). In some examples, the scheduler 310 may sort or reorder the pending task queue 314 as shown by the dotted arrow 301. Subsequently, at 332, the tasks from the pending task queue 314 may be loaded onto the resources 320 for execution according to the schedule and/or resource assignment determined by the scheduler 310. The job(s) and/or tasks(s) that are being executed by the resources 320 are shown by 304. In some examples, the scheduler 310 can utilize an additional queue to track job(s) and/or task(s) that are under execution.

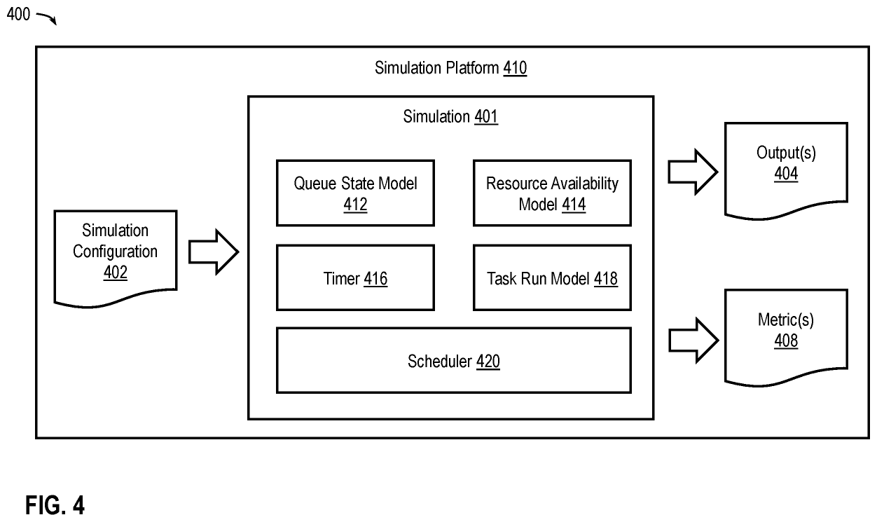

As discussed above, the number of AV simulations and/or AV software builds executed on an infrastructure platform may reach hundreds of thousands per day. As such, scheduling these AV simulations and/or software build can be complex. Accordingly, it may be desirable to be able to reliably predict and/or gain an understanding of how a scheduler may make scheduling decisions. FIGS. 4-6 illustrate various mechanisms for creating a simulation engine to evaluate and/or predict the performance (e.g., scheduling decisions) of a scheduler for AV software builds and/or AV simulations on an infrastructure platform. FIGS. 4-6 may be discussed in relation to each other and in relation to FIGS. 1-3.

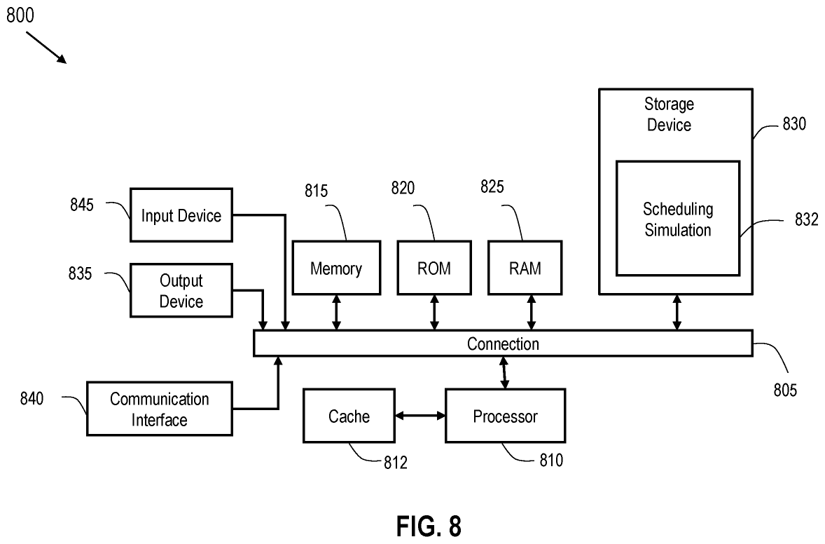

FIG. 4 illustrates an exemplary simulation scheme 400 for evaluating a scheduler 420 for AV software builds and/or AV simulations, according to some embodiments of the present disclosure. In some aspects, the scheduler 420 may be part of the scheduling service layer 120 of FIG. 1. In some aspects, the scheduler 420 may correspond to the scheduler 310. As shown in FIG. 4, the scheme 400 may include a simulation platform 410 for executing a scheduling simulation 401. The simulation platform 410 may be a computer-implemented system. In some examples, the simulation platform 410 may be similar to the simulation platform 756 of FIG. 7 or the processor-based system 800 of FIG. 8. The simulation 401 may simulate operations (or decisions) of the scheduler 420 and execution of tasks as scheduled by the scheduler 420. The simulation 401 may be software program codes that simulate scheduling scenarios.

At a high level, the scheduler 420 may use a queue state model 412 and a resource availability model 414 to determine a schedule for execution of tasks. The queue state model 412 may implement queues (similar to the queues 312 and 314) for queuing job requests, pending scheduled tasks, and/or tasks that are currently under execution. The queue state model 412 may track and/or maintain queue states of those queues. A queue state may refer to a queue size, an availability and/or an occupancy of a queue, priorities of tasks in the queue, and/or an ordering of tasks in the queue. The resource availability model 414 may simulate resources (e.g., the resources 320) to be used for task execution. The simulation 401 may utilize a timer 416 and a task run model 418 to simulate task execution. The simulation of queues, resources, and task execution will be discussed more fully below.

In an aspect, the simulation 401 may be executed according to a simulation configuration 402. The simulation configuration 402 may include a variety of configuration parameters (as shown in FIG. 5) for executing the simulation.

FIG. 5 illustrates an exemplary simulation configuration 402 for evaluating the scheduler 420 for AV software builds and/or AV simulations, according to some embodiments of the present disclosure. As shown in FIG. 5, the simulation configuration 402 may include indications of a number of schedulers 502, a number of workers 504, queue parameters 506, job submissions 508, assertion rules 510, output parameters 512, and metric parameters 514.

In some examples, the scheduler 420 may include multiple schedulers, for example, implementing different scheduling algorithms such as a FIFO scheduling algorithm, a completing time-driven scheduling algorithm, or a gang scheduling algorithm. In some examples, the scheduler 420 can be an adaptive scheduler that dynamically selects one of the implemented schedulers at run time to schedule a task, for example, based on a specific requirement of the task. The number of schedulers 502 may indicate a number of schedulers to be supported by the scheduler 420 for the simulation 401. In some examples, the simulation configuration 402 may also specify the type(s) of scheduling algorithm(s) the scheduler 420 may implement for the simulation 401.

As discussed above, the scheduler 420 may schedule tasks to be executed by simulated resources, which may be modeled by the resource availability model 414. The number of workers 504 may include a number workers (or resources) to be simulated by the resource availability model 414. In some examples, the simulation configuration 402 may also specify at least one of a compute resource capacity (e.g., a number of CPU(s) and/or GPU(s) and respective processing speeds), a storage resource capacity (e.g., sizes of static memory, internal and/or external RAMs, etc.), or a network resource capacity or throughput (e.g., for file upload and/or download) for a hardware platform to be simulated by the resource availability model 414. The capacity for a certain resource may refer to a total or maximum capacity of the respective resource. Additionally or alternatively, the simulation configuration 402 may specify at least one of a compute resource occupancy and/or availability, a storage resource occupancy and/or availability, or a network resource occupancy and/or availability to be simulated by the resource availability model 414 so that a certain scheduling scenario can be evaluated. Additionally or alternatively, the simulation configuration 402 may specify whether the scheduler 420 may spin up a new VM based on demand and/or associated cost. In general, the simulation configuration 402 may specify any parameter associated with resources for the resource availability model 414 to model.

The scheduler 420 may utilize queues (e.g., the queues 312 and/or 314) to store incoming requests (e.g., the job requests 302) for task execution, scheduled tasks (to be executed), tasks that are currently being executed, etc. The simulation configuration 402 may specify queue parameters 506 for configuring queues to be used by the scheduler 420 and simulated by the queue state model 412. The queue parameters 506 may include, for example, but are not limited to, a number of queues, a queue priority for each queue, a size for each queue, a queueing and/or queue storage scheme (e.g., FIFO queueing, priority-based queueing using a single queue, different queues for different priorities, etc.) for the queues. The queue parameters 506 may also specify an initial state of a queue (to be used at the start of the simulation 401), for example, to simulate a certain scheduling scenario. For instance, the queue parameters 506 can specify the task runtime, task start time, task end time for the tasks that are currently being executed by the simulated resources.

To simulate incoming job requests, the simulation configuration 402 may include a list of job submissions 508 (shown as 508a, . . . , 508b), for example, simulating requests from clients such as the clients 110. Each job submission 508 can be in the form of a job specification. For instance, a job specification may include a job identifier (ID), a submission time, and a completion goal for the respective job. The job ID may identify the requested job. The job submission time may simulate when the job is submitted. The completion goal may be a time when the job is expected to be completed. A job may generally include a list of one or more tasks. Each task may be specified by a respective task specification 509. In the example illustrated in FIG. 5, the job submission 508a includes a list of tasks, each specified by a respective one of the task specifications 509a, . . . , 509b. Each task specification 509 may specify a variety of parameters associated with a respective one of the tasks.

In some aspects, the task specification 509a may indicate a task ID (e.g., A1) to identify a respective task from among the list of tasks in the job submission 508a. Additionally or alternatively, the task specification 509a may indicate an amount of time (e.g., a runtime) for executing the task. Additionally or alternatively, the task specification 509 may indicate a downloading time (e.g., a duration) or a file size of a file to be downloaded before and/or during the execution of the task. As an example, a certain file describing a driving scenario to be tested with a certain job or task (e.g., an AV simulation) may be downloaded as part of the task execution, and the simulation 401 (or more specifically the scheduler 420) may account for the file downloading time as part of the scheduling. Additionally or alternatively, the task specification 509a may indicate an uploading time (e.g., a duration) or a file size of a file to be uploaded during and/or after the execution of the task. As an example, a certain file including outputs (e.g., AV driven paths and/or driving decisions) output by a certain task (e.g., an AV simulation) may be uploaded as part of the task execution, and the simulation 401 (or more specifically the scheduler 420) may account for the file uploading time as part of the scheduling. As another example, when a task is for an AV software build, there may be file(s) including driving scenario(s) or test case(s) to be downloaded and tested for the build and file(s) including respective test result(s) to be uploaded. Additionally or alternatively, the task specification 509a may specify a worker class to be used for executing the respective task. As an example, the worker class may specify that 2 CPU cores, 2 GPU core, and 128 GB of RAM may be used for executing the task. Additionally or alternatively, the task specification 509a may specify a priority of the task. As an example, the priority can be high, medium, or low. In other examples, the priority can be a particular priority level (e.g., a priority level of 4 out of a total of 6 priority levels).

To assist evaluation of the scheduler 420, the assertion rules 510 may specify predefined conditions to be validated or scheduling events to be filtered by the simulation 401. In an example, one of the assertion rules 510 may be for validating whether task A1 finishes before task A2. In another example, one of the assertion rules 510 may be for validating whether a job or task runtime is completed within a certain amount of time. In yet another example, one of the assertion rules 510 may be for validating whether a job or task started no later or no earlier than a certain time. In yet another example, one of the assertion rules 510 may be for validating whether a job or task completed no later or no earlier than a certain time. In a further example, one of the assertion rules 510 may be for validating whether the task is preempted by another task or vice versa. In general, the simulation configuration 402 can include any suitable assertion rule(s) 510. In general, an assertion rule 510 is a condition for which the simulation 401 may monitor and report upon a detection of the condition.

The output parameters 512 may specify the types of outputs 404 to be generated by the simulation 401. For instance, the output parameters 512 may specify certain data to be generated for further inspection. As an example, one of the output parameters 512 may specify that a queue state (of certain queue(s) in the queue state model 412) at a certain time to be output, which may be used as a precondition for a subsequent task execution, for example. As another example, one of the output parameters 512 may specify a time and/or resource log of all tasks executed over a certain duration. As a further example, one of the output parameters 512 may specify that validation results from the assertion rules 510 to be output. In general, the output parameters 512 may specify any suitable parameters to be used for evaluating the performance of the scheduler 420.

The metric parameters 514 may specify the types of metrics 408 to be used for evaluating the performance of the scheduler 420. As an example, one of the metric parameters 514 may specify a metric to be calculated based on a comparison of a runtime of a task against a completion goal specified for the task (in a respective task specification 509). As another example, one of the metric parameters 514 may specify a metric to be calculated based on an ordering of jobs or tasks to be completed. As a further example, one of the metric parameters 514 may specify a metric to be calculated based on priorities of tasks that are completed within a certain duration (e.g., a number of minutes, hours, days, etc.). In some examples, a calculated metric can be a binary value indicating a pass or a failure. In other examples, a calculated metric can be a numerical score (e.g., within a certain range).

In general, the configuration 402 may include any suitable combinations of indications of the number of schedulers 502, the number of workers 504, the queue parameters 506, the job submissions 508, the assertion rules 510, the output parameters 512, and the metric parameters 514.

Returning to FIG. 4, the queue state model 412 may configure queues according to the queue parameters 506 as specified by the simulation configuration 402. For instance, the queue state model 412 may create one or more queues to be used by the scheduler 420 to queue job requests, pending scheduled tasks, and/or currently executed tasks. The queue state model 412 may configure a number of entries for each queue, a number of queues, and/or a queuing structure (e.g., FIFO queueing, priority-based queueing using a single queue, different queues for different priorities, etc.) according to the queue parameters 506. The queue state model 412 may configure the state of each queue (e.g., a priority and/or a number of tasks currently queued at each queue) before the simulation 401 starts. In general, the queue state model 412 may implement queues (e.g., a task request queue, a pending task queue, a task under execution queue, etc.) similar to queues that are used by the scheduler 420 when the scheduler 420 is deployed for scheduling job(s) and/or task(s) on real infrastructure resources. As an example, the scheduler 420 may store a job submission in a task request queue, determine a schedule for task(s) in the job submission, store the scheduled task(s) in a pending task queue, and move a scheduled task to a task under execution queue when the execution of the task begins, etc.

The resource availability model 414 may simulate resources, such as compute resources, storage resources, and/or network resources (e.g., cloud resources similar to the cloud platform 130 and/or worker pool similar to the worker pool 240). The scheduler 420 may assign or allocate resources from the simulated resources for executing tasks (e.g., specified by the task specifications 509). The resource availability model 414 may simulate a certain amount or capacity of a resource, for example, according to at least one of a compute resource capacity (e.g., CPU(s) and/or GPU(s) and associated processing speeds), a storage resource capacity (e.g., static memory, internal and/or external RAMs, etc.), or a network resource capacity or throughput (e.g., for file upload and/or download) for executing tasks scheduled by the scheduler 420) according to the queue parameters 506 as specified by the simulation configuration 402. In some examples, the resource availability model 414 may initialize an availability of a certain resource, for example, according to at least one of a compute resource availability or occupancy, a storage resource availability or occupancy, or a network resource availability or occupancy as specified by the simulation configuration 402.

The simulated resources are virtual resources or synthetic resources. The is no actual resource (or real-world resource) being assigned or released. The resource availability model 414 may generally utilize any suitable data structure to maintain and track the amounts of resources that are being used (e.g., as the scheduler 420 assigns certain resources for task execution) and/or the amounts of resources that are available (e.g., as tasks are completed and the assigned or allocated resources are released). As an example, if the resource availability model 414 simulates a compute resource capacity of 10 total CPU cores, the resource availability model 414 may initialize a number of CPU cores to 10. If the scheduler 420 assigns 2 CPU cores to a certain task, the resource availability model 414 may update the number of available CPU cores to 8 and the number of occupied CPU cores to 2. As another example, if the resource availability model 414 simulates a total of 10 workers of a particular worker class (e.g., including 2 CPU cores, 2 GPU cores, 256 GB of RAM), the resource availability model 414 may initialize a number of workers of the particular worker class to 10. If the scheduler 420 assigns 2 workers of the particular worker class to a certain task, the resource availability model 414 may update the number of available workers for the particular worker class to 8 and the number of occupied workers for the particular worker class to 2. In general, the resource availability model 414 can maintain and track resource usage and/or availability at any suitable granularity levels (e.g., at levels of CPU cores, GPU cores, memory, and/or workers). In general, the simulation 401 can be configured to simulate any workload by configuring the queue state model 412 (e.g., by setting a number of incoming job and/or task requests, a number of pending scheduled tasks, a number of currently tasks under execution, runtime for each of those tasks, etc.) and the resource availability model 414 (e.g., by setting a total resource capacity and an occupancy or availability for each resource).

The timer 416 may generate time ticks, simulating time durations of a certain real-time unit. As an example, the timer 416 may advance a time or generate a time tick every 100 ms to simulate that 1 second (in real-time) has elapsed. The task run model 418 may simulate execution of tasks without actually running any of the tasks on real resources. As an example, a task may have a start time, a runtime, and a completion time. The task run model 418 may utilize the simulated timeline provided by the timer 416. The task run model 418 may simulate the start of a task execution, the duration of the task execution, and the completion of the task execution based on the simulated timeline. That is, a task can be executed in the simulation 401 faster than when the task is executed in real time on real resources.

In some aspects, the task run model 418 and the resource availability model 414 may coordinate with each other to simulate task execution on the simulated resources. For instance, the resource availability model 414 may update the availability of the simulated resources based on when a task execution starts and when a task execution is completed. That is, the resource availability model 414 may simulate the occupancy of a certain resource used by a certain task when the task run model 418 indicates that the task is being executed on the resource.

The scheduler 420 may determine a schedule for executing tasks as specified by the job submissions (e.g., the job submissions 508) in the simulation configuration 402. As discussed above, the tasks may be associated with at least one of an AV software build (e.g., for a code release) or an AV simulation (e.g., simulating perception, prediction, planning, and/or control). Thus, as part of determining the schedule, the scheduler 420 may estimate a runtime based on a driving scenario associated with a requested task. The driving scenario may include information or a configuration related to a road condition (e.g., a road gradient, a road textures pot-holes, etc.), a certain city, a weather condition (e.g., sun, rain, snow, fog, etc.), and/or road assets (e.g., placement of roadways, buildings, pedestrians, other vehicles, etc.). As an example, the scheduler 420 may determine a longer runtime when a driving scenario is more complex, requires more scenario data to be downloaded for the execution, and/or have a longer duration and may determine a shorter runtime when a driving scenario is less complex, requires less scenario data to be downloaded for the execution, and/or have a shorter duration. As another example, testing for a certain driving scenario can be repeatedly executed multiple times to validate if the AV (e.g., the AV software or the AV simulation) is able to repeatedly, consistently handle the driving condition. As such, the scheduler 420 may determine a runtime for a task based on the number of repetitions to be executed for the task. In some examples, a job submission can include an indication of a driving scenario for a task, and thus the scheduler 420 may identify the driving scenario by parsing the job submission. In some examples, changes to AV software builds and/or AV simulations may be under the control of a certain configuration management tool, where different AV software builds or different AV simulations may be originated from different software configuration branches. Accordingly, the scheduler 420 may determine a driving scenario for a task based on a software configuration branch from which the software program for the task is originated.

Additionally or alternatively, as part of determining the schedule, the scheduler 420 may estimate a runtime based on a vehicle compute framework (e.g., perception, prediction, planning, and/or control) associated with a requested task. For instance, the scheduler 420 may estimate a longer runtime for a task related to perception and/or prediction than a task related to planning and/or control based on prior knowledge that perception and/or prediction may utilize ML algorithms that are computationally intensive. Some other examples of vehicle compute framework may be associated with the types of AV simulators or AV simulations (e.g., a replay of a data log collected from a real-world driving session, simulation and/or animation of road assets and/or non-player character (NPC), and/or simulation of synthetic driving scenarios, simulation of map and geographical locations, etc.), and thus the scheduler 420 may estimate a runtime for the requested task based on timing information related to the data log. In general, the scheduler 420 may estimate a runtime for a task based on at least one of an associated vehicle compute framework and/or associated historical trends. In some examples, a job submission can include an indication of a vehicle compute framework for a task, and thus the scheduler 420 may identify the vehicle compute framework by parsing the job submission. In some examples, the scheduler 420 may determine a vehicle compute framework for a task based on a software configuration branch from which the software program for the task is originated. Additionally, there may be other performance testing workloads that are scheduled on the computer(s) to be used for executing a certain task. Those performance testing workloads may have different execution characteristics (e.g., priorities, maximum, minimum, and/or average execution time, whether preemptions are allowed, etc.), which may impact the runtime of the task. As such, the scheduler 420 may estimate the task runtime based on the execution characteristics of those workloads.

Additionally or alternatively, as part of determining the schedule, the scheduler 420 may determine the schedule based on a task category associated with a requested task. For instance, the scheduler 420 may determine whether the requested task is associated with a first task category (e.g., related to an AV software build) or a second task category (e.g., related to ab AV simulation that simulates operations of an AV) and may prioritize a task of the first task category over a task of the second category. In an example, the first task category may be related to an AV software build, and the second task category may be related to an AV simulation that simulates operations of an AV. That is, the scheduler 420 may prioritize a first task related to an AV software build (e.g., requested by a release engineer) over a second task related to an AV simulation (e.g., requested by a developer). That is, the first task may scheduler to run before the second task. Furthermore, the scheduler 420 may prioritize tasks for AV software builds based on respective release dates. For instance, the scheduler 420 may prioritize a task for an AV software build having an earlier release date than a task for an AV software build having a later release date.

In some aspects, the simulation 401 may validate scheduling decisions made by the scheduler 420, generate the one or more outputs 404, and calculate one or more metrics 408 according to respective assertion rules 510, output parameters 512, and metric parameter 514 specified by the simulation configuration 402 as discussed above with reference to FIG. 5. As an example, a metric 408 may be calculated based on a comparison of a completion time of a task to a completion goal for the task. As another example, a metric 408 may be calculated based on an ordering of tasks scheduled by the scheduler. As another example, a metric 408 may be calculated based on priorities of tasks executed over a certain time duration. The metrics 408 can be in any suitable form. For instance, a metric 408 can be a binary score with an indication of a pass or fail (e.g., whether a task is completed within the completion goal or not). In other examples, the metric can be a numerical score (e.g., based on a number of tasks scheduled or executed over a certain time duration matches a predefined order). As a further example, a metric 408 may be calculated based on the task scheduling order determined by the scheduler 420. For instance, the simulation 401 may assert if a higher priority task is appropriately pushed ahead of lower priority tasks in a queue (e.g., the pending task queue 314). To calculate the metric 408, the simulation 401 may evaluate the state of the queue after a scheduling decision is made by the scheduler 420.

In some aspects, the simulation 401 may be executed with different combinations of scheduling factors (e.g., a queue state, a task priority, a task deadline, a resource availability, a driving scenario (or use case), and/or a vehicle compute framework), and the metrics 408 obtained for the different combinations can be used to predict scheduling decisions or behaviors of the scheduler 420. In some aspects, the scheduler 420 can be modified based on the metrics 408, for example, to improve resource utilization and/or task execution efficiency. In some aspects, when utilizing adaptive scheduling with multiple schedulers of different scheduling types (or strategies), the scheduler 420 can be designed or trained to select a most suitable scheduler for adaptive scheduling based on feedback from the metrics 408.

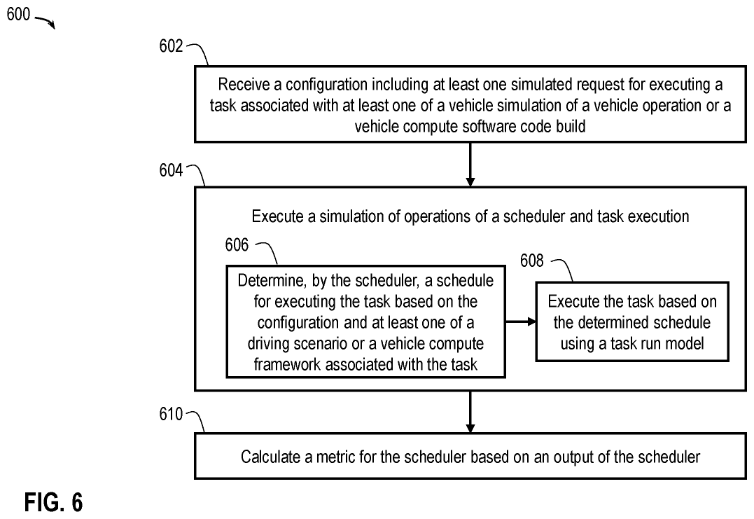

FIG. 6 is a flow diagram illustrating an exemplary scheduler simulation process 600, according to some embodiments of the present disclosure. The process 600 can be implemented by a computer-implemented system (e.g., the simulation platform 410 of FIG. 4, the simulation platform 756 of FIG. 7, and/or the system 800 of FIG. 8). In general, the process 600 may be performed using any suitable hardware components and/or software components. The process 600 may utilize similar mechanisms discussed above with reference to FIGS. 1-5. Operations are illustrated once each and in a particular order in FIG. 6, but the operations may be performed in parallel, reordered, and/or repeated as desired.

At 602, the computer-implemented system may receive a configuration including at least one simulated request for executing a task. The task may be associated with at least one of a vehicle simulation of a vehicle operation or a vehicle compute software build. The configuration may be similar to the configuration 402 discussed above with reference to FIGS. 4-5. For instance, the configuration may further include an indication of at least one of a queue size or a number of pending tasks associated with a queue state model (e.g., the queue state model 412). Additionally or alternatively, the configuration may include an indication of at least one of a compute resource capacity, a storage resource capacity, or a network resource capacity for a hardware platform associated with a resource availability model (e.g., the resource availability model 414). Additionally or alternatively, the configuration may include an indication of at least one of a compute resource occupancy, a storage resource occupancy, or a network resource occupancy for a hardware platform associated with the resource availability model. Additionally or alternatively, the configuration may include an indication of at least one of a task priority, a task runtime, a task completion goal, a file downloading time duration (e.g., for downloading driving scenario and/or road asset files), or a file downloading time duration (e.g., for uploading output files including driving paths, driving decisions, and/or driving performances from simulation and/or software tests) associated with the task.

At 604, the computer-implemented system may execute a simulation of operations of a scheduler and task execution. The simulation may be similar to the simulation 401 discussed above with reference to FIG. 4. The scheduler may be similar to the scheduling service layer 120 of FIG. 1, the scheduler 310 of FIG. 3, and/or the scheduler 420 of FIG. 4 discussed above. For instance, at 606, as part of executing the simulation, the computer-implemented system may determine, by the scheduler, a schedule for running the task based on at least one of a driving scenario or a vehicle compute framework associated with the task. At 608, as part of executing the simulation, the computer-implemented system may further perform the task execution using a task run model (e.g., the task run model 418).

In some aspects, as part of determining the schedule for the task, the computer-implemented system may estimate a runtime for the task based on the driving scenario and/or the vehicle compute framework associated with the task and determine the schedule based on the estimated runtime. In an example, the driving scenario may include information associated with at least one of a road condition, a city, a weather condition, or a road asset. In an example, the vehicle compute framework may be one of a perception compute framework (for determining a perception of an AV surroundings), a prediction compute framework (for predicting a future motion of the AV or a traffic participant), a planning compute framework (for planning a driving path for the AV), or a replay framework (for replaying a driving scenario, for example, based on driving logs captured from driving in a real-world roadways). In some aspects, the determining the schedule for the task may be further based on a task category of the task, the vehicle simulation is associated with a first task category, and the vehicle software build may be associated with a second task category different than the first task category. In some aspects, as part of determining the schedule for the task, the computer-implemented system may determine at least one of a task start time, a task runtime, or a task completion time for the task. In some aspects, as part of executing the simulation, the computer-implemented system may validate the at least one of a task start time, a task runtime, or a task completion time against a predefined condition.

At 610, the computer-implemented system may calculate a metric (e.g., the metric(s) 408) for the scheduler based on one or more outputs (e.g., the output(s) 404) of the simulation. As part of calculating the metric, the computer-implemented system may compare a completion time of the task and a completion goal for the task. In some aspects, the calculation of the metric may be based on an ordering of tasks scheduled by the scheduler. In some aspects, the calculation of the metric may be based on priorities of tasks executed over a certain time duration.

Turning now to FIG. 7, this figure illustrates an example of an AV management system 700. One of ordinary skill in the art will understand that, for the AV management system 700 and any system discussed in the present disclosure, there may be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 700 includes an AV 702, a data center 750, and a client computing device 770. The AV 702, the data center 750, and the client computing device 770 may communicate with one another over one or more networks (not shown), such as a public network (e.g., the Internet, an Infrastructure as a Service (IaaS) network, a Platform as a Service (PaaS) network, a Software as a Service (SaaS) network, another Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 702 may navigate about roadways without a human driver based on sensor signals generated by multiple sensor systems 704, 706, and 708. The sensor systems 704-708 may include different types of sensors and may be arranged about the AV 702. For instance, the sensor systems 704-708 may comprise IMUs, cameras (e.g., still image cameras, video cameras, etc.), light sensors (e.g., LIDAR systems, ambient light sensors, infrared sensors, etc.), RADAR systems, a Global Navigation Satellite System (GNSS) receiver, (e.g., Global Positioning System (GPS) receivers), audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 704 may be a camera system, the sensor system 706 may be a LIDAR system, and the sensor system 708 may be a RADAR system. Other embodiments may include any other number and type of sensors.

AV 702 may also include several mechanical systems that may be used to maneuver or operate AV 702. For instance, the mechanical systems may include vehicle propulsion system 730, braking system 732, steering system 734, safety system 736, and cabin system 738, among other systems. Vehicle propulsion system 730 may include an electric motor, an internal combustion engine, or both. The braking system 732 may include an engine brake, a wheel braking system (e.g., a disc braking system that utilizes brake pads), hydraulics, actuators, and/or any other suitable componentry configured to assist in decelerating AV 702. The steering system 734 may include suitable componentry configured to control the direction of movement of the AV 702 during navigation. Safety system 736 may include lights and signal indicators, a parking brake, airbags, and so forth. The cabin system 738 may include cabin temperature control systems, in-cabin entertainment systems, and so forth. In some embodiments, the AV 702 may not include human driver actuators (e.g., steering wheel, handbrake, foot brake pedal, foot accelerator pedal, turn signal lever, window wipers, etc.) for controlling the AV 702. Instead, the cabin system 738 may include one or more client interfaces (e.g., Graphical User Interfaces (GUIs), Voice User Interfaces (VUIs), etc.) for controlling certain aspects of the mechanical systems 730-638.

AV 702 may additionally include a local computing device 710 that is in communication with the sensor systems 704-708, the mechanical systems 730-738, the data center 750, and the client computing device 770, among other systems. The local computing device 710 may include one or more processors and memory, including instructions that may be executed by the one or more processors. The instructions may make up one or more software stacks or components responsible for controlling the AV 702; communicating with the data center 750, the client computing device 770, and other systems; receiving inputs from riders, passengers, and other entities within the AV's environment; logging metrics collected by the sensor systems 704-708; and so forth. In this example, the local computing device 710 includes a perception stack 712, a mapping and localization stack 714, a planning stack 716, a control stack 718, a communications stack 720, a High Definition (HD) geospatial database 722, and an AV operational database 724, among other stacks and systems.

Perception stack 712 may enable the AV 702 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 704-708, the mapping and localization stack 714, the HD geospatial database 722, other components of the AV, and other data sources (e.g., the data center 750, the client computing device 770, third-party data sources, etc.). The perception stack 712 may detect and classify objects and determine their current and predicted locations, speeds, directions, and the like. In addition, the perception stack 712 may determine the free space around the AV 702 (e.g., to maintain a safe distance from other objects, change lanes, park the AV, etc.). The perception stack 712 may also identify environmental uncertainties, such as where to look for moving objects, flag areas that may be obscured or blocked from view, and so forth.

Mapping and localization stack 714 may determine the AV's position and orientation (pose) using different methods from multiple systems (e.g., GPS, IMUs, cameras, LIDAR, RADAR, ultrasonic sensors, the HD geospatial database 722, etc.). For example, in some embodiments, the AV 702 may compare sensor data captured in real-time by the sensor systems 704-708 to data in the HD geospatial database 722 to determine its precise (e.g., accurate to the order of a few centimeters or less) position and orientation. The AV 702 may focus its search based on sensor data from one or more first sensor systems (e.g., GPS) by matching sensor data from one or more second sensor systems (e.g., LIDAR). If the mapping and localization information from one system is unavailable, the AV 702 may use mapping and localization information from a redundant system and/or from remote data sources.

The planning stack 716 may determine how to maneuver or operate the AV 702 safely and efficiently in its environment. For example, the planning stack 716 may receive the location, speed, and direction of the AV 702, geospatial data, data regarding objects sharing the road with the AV 702 (e.g., pedestrians, bicycles, vehicles, ambulances, buses, cable cars, trains, traffic lights, lanes, road markings, etc.) or certain events occurring during a trip (e.g., an Emergency Vehicle (EMV) blaring a siren, intersections, occluded areas, street closures for construction or street repairs, Double-Parked Vehicles (DPVs), etc.), traffic rules and other safety standards or practices for the road, user input, and other relevant data for directing the AV 702 from one point to another. The planning stack 716 may determine multiple sets of one or more mechanical operations that the AV 702 may perform (e.g., go straight at a specified speed or rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 716 may select from multiple backup plans to carry out. For example, while preparing to change lanes to turn right at an intersection, another vehicle may aggressively cut into the destination lane, making the lane change unsafe. The planning stack 716 could have already determined an alternative plan for such an event, and upon its occurrence, help to direct the AV 702 to go around the block instead of blocking a current lane while waiting for an opening to change lanes.

The control stack 718 may manage the operation of the vehicle propulsion system 730, the braking system 732, the steering system 734, the safety system 736, and the cabin system 738. The control stack 718 may receive sensor signals from the sensor systems 704-708 as well as communicate with other stacks or components of the local computing device 710 or a remote system (e.g., the data center 750) to effectuate operation of the AV 702. For example, the control stack 718 may implement the final path or actions from the multiple paths or actions provided by the planning stack 716. Implementation may involve turning the routes and decisions from the planning stack 716 into commands for the actuators that control the AV's steering, throttle, brake, and drive unit.

In some aspects, the perception stack 712, the localization stack 714, the planning stack 716, and the control stack 718 may be part of an AV compute software, where job(s) or task(s) for building the AV compute software may be scheduled by a scheduler similar to the scheduler 420 and executed on infrastructure resources as discussed herein.

The communication stack 720 may transmit and receive signals between the various stacks and other components of the AV 702 and between the AV 702, the data center 750, the client computing device 770, and other remote systems. The communication stack 720 may enable the local computing device 710 to exchange information remotely over a network, such as through an antenna array or interface that may provide a metropolitan WIFI® network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (L7), Citizens Broadband Radio Service (CBRS), MULTEFIRE, etc.). The communication stack 720 may also facilitate local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 722 may store HD maps and related data of the streets upon which the AV 702 travels. In some embodiments, the HD maps and related data may comprise multiple layers, such as an areas layer, a lanes and boundaries layer, an intersections layer, a traffic controls layer, and so forth. The areas layer may include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer may include geospatial information of road lanes (e.g., lane or road centerline, lane boundaries, type of lane boundaries, etc.) and related attributes (e.g., direction of travel, speed limit, lane type, etc.). The lanes and boundaries layer may also include 3D attributes related to lanes (e.g., slope, elevation, curvature, etc.). The intersections layer may include geospatial information of intersections (e.g., crosswalks, stop lines, turning lane centerlines, and/or boundaries, etc.) and related attributes (e.g., permissive, protected/permissive, or protected only left turn lanes; permissive, protected/permissive, or protected only U-turn lanes; permissive or protected only right turn lanes; etc.). The traffic controls layer may include geospatial information of traffic signal lights, traffic signs, and other road objects and related attributes.

The AV operational database 724 may store raw AV data generated by the sensor systems 704-708 and other components of the AV 702 and/or data received by the AV 702 from remote systems (e.g., the data center 750, the client computing device 770, etc.). In some embodiments, the raw AV data may include HD LIDAR point cloud data, image or video data, RADAR data, GPS data, and other sensor data that the data center 750 may use for creating or updating AV geospatial data.

The data center 750 may be a private cloud (e.g., an enterprise network, a co-location provider network, etc.), a public cloud (e.g., an IaaS network, a PaaS network, a SaaS network, or other CSP network), a hybrid cloud, a multi-cloud, and so forth. The data center 750 may include one or more computing devices remote to the local computing device 710 for managing a fleet of AVs and AV-related services. For example, in addition to managing the AV 702, the data center 750 may also support a ridesharing service, a delivery service, a remote/roadside assistance service, street services (e.g., street mapping, street patrol, street cleaning, street metering, parking reservation, etc.), and the like.

The data center 750 may send and receive various signals to and from the AV 702 and the client computing device 770. These signals may include sensor data captured by the sensor systems 704-708, roadside assistance requests, software updates, ridesharing pick-up and drop-off instructions, and so forth. In this example, the data center 750 includes one or more of a data management platform 752, an Artificial Intelligence/Machine Learning (AI/ML) platform 754, a simulation platform 756, a remote assistance platform 758, a ridesharing platform 760, and a map management platform 762, among other systems.

Data management platform 752 may be a “big data” system capable of receiving and transmitting data at high speeds (e.g., near real-time or real-time), processing a large variety of data, and storing large volumes of data (e.g., terabytes, petabytes, or more of data). The varieties of data may include data having different structures (e.g., structured, semi-structured, unstructured, etc.), data of different types (e.g., sensor data, mechanical system data, ridesharing service data, map data, audio data, video data, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 750 may access data stored by the data management platform 752 to provide their respective services.

The AI/ML platform 754 may provide the infrastructure for training and evaluating machine learning algorithms for operating the AV 702, the simulation platform 756, the remote assistance platform 758, the ridesharing platform 760, the map management platform 762, and other platforms and systems. Using the AI/ML platform 754, data scientists may prepare data sets from the data management platform 752; select, design, and train machine learning models; evaluate, refine, and deploy the models; maintain, monitor, and retrain the models; and so on.

The simulation platform 756 may enable testing and validation of the algorithms, ML models, neural networks, and other development efforts for the AV 702, the remote assistance platform 758, the ridesharing platform 760, the map management platform 762, and other platforms and systems. The simulation platform 756 may replicate a variety of driving environments and/or reproduce real-world scenarios from data captured by the AV 702, including rendering geospatial information and road infrastructure (e.g., streets, lanes, crosswalks, traffic lights, stop signs, etc.) obtained from the map management platform 762; modeling the behavior of other vehicles, bicycles, pedestrians, and other dynamic elements; simulating inclement weather conditions, different traffic scenarios; and so on. In some embodiments, the simulation platform 756 may include a scheduling simulation block 757 that simulates operations of a scheduler (e.g., the scheduler 420) and task execution and generates a metric for the scheduler as discussed herein.

The remote assistance platform 758 may generate and transmit instructions regarding the operation of the AV 702. For example, in response to an output of the AI/ML platform 754 or other system of the data center 750, the remote assistance platform 758 may prepare instructions for one or more stacks or other components of the AV 702.

The ridesharing platform 760 may interact with a customer of a ridesharing service via a ridesharing application 772 executing on the client computing device 770. The client computing device 770 may be any type of computing system, including a server, desktop computer, laptop, tablet, smartphone, smart wearable device (e.g., smart watch; smart eyeglasses or other Head-Mounted Display (TIMID); smart ear pods or other smart in-ear, on-ear, or over-ear device; etc.), gaming system, or other general-purpose computing device for accessing the ridesharing application 772. The client computing device 770 may be a customer's mobile computing device or a computing device integrated with the AV 702 (e.g., the local computing device 710). The ridesharing platform 760 may receive requests to be picked up or dropped off from the ridesharing application 772 and dispatch the AV 702 for the trip.

Map management platform 762 may provide a set of tools for the manipulation and management of geographic and spatial (geospatial) and related attribute data. The data management platform 752 may receive LIDAR point cloud data, image data (e.g., still image, video, etc.), RADAR data, GPS data, and other sensor data (e.g., raw data) from one or more AVs 702, Unmanned Aerial Vehicles (UAVs), satellites, third-party mapping services, and other sources of geospatially referenced data. The raw data may be processed, and map management platform 762 may render base representations (e.g., tiles (2D), bounding volumes (3D), etc.) of the AV geospatial data to enable users to view, query, label, edit, and otherwise interact with the data. Map management platform 762 may manage workflows and tasks for operating on the AV geospatial data. Map management platform 762 may control access to the AV geospatial data, including granting or limiting access to the AV geospatial data based on user-based, role-based, group-based, task-based, and other attribute-based access control mechanisms. Map management platform 762 may provide version control for the AV geospatial data, such as to track specific changes that (human or machine) map editors have made to the data and to revert changes when necessary. Map management platform 762 may administer release management of the AV geospatial data, including distributing suitable iterations of the data to different users, computing devices, AVs, and other consumers of ID maps. Map management platform 762 may provide analytics regarding the AV geospatial data and related data, such as to generate insights relating to the throughput and quality of mapping tasks.

In some embodiments, the map viewing services of map management platform 762 may be modularized and deployed as part of one or more of the platforms and systems of the data center 750. For example, the AI/ML platform 754 may incorporate the map viewing services for visualizing the effectiveness of various object detection or object classification models, the simulation platform 756 may incorporate the map viewing services for recreating and visualizing certain driving scenarios, the remote assistance platform 758 may incorporate the map viewing services for replaying traffic incidents to facilitate and coordinate aid, the ridesharing platform 760 may incorporate the map viewing services into the client application 772 to enable passengers to view the AV 702 in transit en route to a pick-up or drop-off location, and so on.

FIG. 8 illustrates an example processor-based system with which some aspects of the subject technology may be implemented. For example, processor-based system 800 may be any computing device making up, or any component thereof in which the components of the system are in communication with each other using connection 805. Connection 805 may be a physical connection via a bus, or a direct connection into processor 810, such as in a chipset architecture. Connection 805 may also be a virtual connection, networked connection, or logical connection.

In some embodiments, computing system 800 is a distributed system in which the functions described in this disclosure may be distributed within a datacenter, multiple data centers, a peer network, etc. In some embodiments, one or more of the described system components represents many such components each performing some or all of the function for which the component is described. In some embodiments, the components may be physical or virtual devices.

Example system 800 includes at least one processing unit (CPU or processor) 810 and connection 805 that couples various system components including system memory 815, such as Read-Only Memory (ROM) 820 and RAM 825 to processor 810. Computing system 800 may include a cache of high-speed memory 812 connected directly with, in close proximity to, or integrated as part of processor 810.

Processor 810 may include any general-purpose processor and a hardware service or software service, such as a scheduling simulation software 832 (e.g., including a queue state model 412, a resource availability model 414, a timer, a task run model 418, and a scheduler 420 of FIG. 4) stored in storage device 830, configured to control processor 810 as well as a special-purpose processor where software instructions are incorporated into the actual processor design. The scheduling simulation software 832 may receive a simulation configuration (e.g., the simulation configuration 402), execute a simulation (e.g., the simulation 401) of operations of a scheduler and task execution, and generate a metric for the scheduler as discussed herein. Processor 810 may essentially be a completely self-contained computing system, containing multiple cores or processors, a bus, memory controller, cache, etc. A multi-core processor may be symmetric or asymmetric.

To enable user interaction, computing system 800 includes an input device 845, which may represent any number of input mechanisms, such as a microphone for speech, a touch-sensitive screen for gesture or graphical input, keyboard, mouse, motion input, speech, etc. Computing system 800 may also include output device 835, which may be one or more of a number of output mechanisms known to those of skill in the art. In some instances, multimodal systems may enable a user to provide multiple types of input/output to communicate with computing system 800. Computing system 800 may include communications interface 840, which may generally govern and manage the user input and system output. The communication interface may perform or facilitate receipt and/or transmission wired or wireless communications via wired and/or wireless transceivers, including those making use of an audio jack/plug, a microphone jack/plug, a USB port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 802.11 Wi-Fi® wireless signal transfer, WLAN signal transfer, Visible Light Communication (VLC) signal transfer, Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communication interface 840 may also include one or more GNSS receivers or transceivers that are used to determine a location of the computing system 800 based on receipt of one or more signals from one or more satellites associated with one or more GNSS systems. GNSS systems include, but are not limited to, the US-based GPS, the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 830 may be a non-volatile and/or non-transitory and/or computer-readable memory device and may be a hard disk or other types of computer-readable media which may store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a Compact Disc (CD) Read Only Memory (CD-ROM) optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another Integrated Circuit (IC) chip/card, RAM, Static RAM (SRAM), Dynamic RAM (DRAM), ROM, Programmable ROM (PROM), Erasable PROM (EPROM), Electrically Erasable PROM (EEPROM), flash EPROM (FLASHEPROM), cache memory (L1/L2/L3/L4/L5/L#), Resistive RAM (RRAM/ReRAM), Phase Change Memory (PCM), Spin Transfer Torque RAM (STT-RAM), another memory chip or cartridge, and/or a combination thereof.

Storage device 830 may include software services, servers, services, etc., that when the code that defines such software is executed by the processor 810, it causes the system 800 to perform a function. In some embodiments, a hardware service that performs a particular function may include the software component stored in a computer-readable medium in connection with the necessary hardware components, such as processor 810, connection 805, output device 835, etc., to carry out the function.

Embodiments within the scope of the present disclosure may also include tangible and/or non-transitory computer-readable storage media or devices for carrying or having computer-executable instructions or data structures stored thereon. Such tangible computer-readable storage devices may be any available device that may be accessed by a general-purpose or special purpose computer, including the functional design of any special purpose processor as described above. By way of example, and not limitation, such tangible computer-readable devices may include RAM, ROM, EEPROM, CD-ROM or other optical disk storage, magnetic disk storage or other magnetic storage devices, or any other device which may be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network Personal Computers (PCs), minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

### SELECTED EXAMPLES

Example 1 includes a computer-implemented system, including one or more processing units; and one or more non-transitory computer-readable media storing instructions, when executed by the one or more processing units, cause the one or more processing units to perform operations including receiving a configuration including a simulated request for executing a task associated with at least one of a vehicle software build or a vehicle simulation of a vehicle; executing a simulation of operations of a scheduler and task execution, where the executing includes determining, by the scheduler, a schedule for executing the task based on the configuration and at least one of a driving scenario or a vehicle compute framework associated with the task; and executing, based on the determined schedule, the task using a task run model (that simulates execution of the task without running the task on actual resources); and calculating a metric for the scheduler based on an output of the simulation.

In Example 2, the computer-implemented system of example 1 can optionally include where the determining the schedule includes estimating a runtime for the task based on the driving scenario.

In Example 3, the computer-implemented system of any one of examples 1-2 can optionally include where the driving scenario includes information associated with at least one of a road condition, a city, a weather condition, or a road asset.

In Example 4, the computer-implemented system of any one of examples 1-3 can optionally include where the determining the schedule includes estimating a runtime for the task based on the vehicle compute framework associated with the task.

In Example 5, the computer-implemented system of any one of examples 1-4 can optionally include where the vehicle compute framework is one of a perception compute framework, a prediction compute framework, a planning compute framework, or a driving scenario replay framework.

In Example 6, the computer-implemented system of any one of examples 1-5 can optionally include where the determining the schedule is further based on whether the task is associated with a first task category or a second task category, the vehicle simulation is in the first task category, and the vehicle software build is in the second task category.

In Example 7, the computer-implemented system of any one of examples 1-6 can optionally include where the configuration further includes an indication of at least one of a queue size or a number of pending tasks associated with a queue state model.

In Example 8, the computer-implemented system of any one of examples 1-7 can optionally include where the configuration further includes an indication of at least one of a compute resource capacity, a storage resource capacity, or a network resource capacity for a hardware platform associated with a resource availability model.

In Example 9, the computer-implemented system of any one of examples 1-8 can optionally include where the configuration further includes an indication of at least one of a compute resource occupancy, a storage resource occupancy, or a network resource occupancy for a hardware platform associated with a resource availability model.

In Example 10, the computer-implemented system of any one of examples 1-9 can optionally include where the configuration further includes an indication of at least one of a priority, a runtime, a task completion goal, a file uploading time duration, or a file downloading time duration associated with the task.

In Example 11, the computer-implemented system of any one of examples 1-10 can optionally include where the executing the simulation further includes validating at least one of a task start time, a task runtime, or a task completion time against a predefined condition.

In Example 12, the computer-implemented system of any one of examples 1-11 can optionally include where the calculating the metric for the scheduler is based on a comparison between a completion time of the task and a completion goal for the task.

In Example 13, the computer-implemented system of any one of examples 1-12 can optionally include where the calculating the metric for the scheduler is based on an ordering of tasks scheduled by the scheduler.

In Example 14, the computer-implemented system of any one of examples 1-13 can optionally include where the calculating the metric for the scheduler is based on priorities of tasks executed over a certain time duration.

Example 15 includes a computer-implemented method, the method including receiving a configuration including a simulated request for executing a task, the task associated with at least one of a vehicle simulation of a vehicle operation or a vehicle software build; executing a simulation of operations of a scheduler and task execution, where the executing includes determining, by the scheduler, a schedule for executing the task based on the configuration and at least one of a driving scenario or a vehicle compute framework associated with the task; and executing, based on the determined schedule, the task using a task run model; and calculating a metric for the scheduler based on an output of the simulation.

In Example 16, the computer-implemented method of example 15 can optionally include where the determining the schedule includes estimating a runtime for the task based on a driving scenario associated with the task, and the driving scenario includes information associated with at least one of a road condition, a city, a weather condition, or a road asset.

In Example 17, the computer-implemented method of any one of examples 15-16 can optionally include where the determining the schedule includes estimating a runtime for the task based on a vehicle compute framework associated with the task, and the vehicle compute framework is one of a perception compute framework, a prediction compute framework, a planning compute framework, or a driving scenario replay framework.

In Example 18, the computer-implemented method of any one of examples 15-17 can optionally include where the determining the schedule is further based on whether the task is associated with a first task category or a second task category, the vehicle simulation is in the first task category, and the vehicle software build is in the second task category.

Example 19 includes one or more non-transitory, computer-readable media encoded with instructions that, when executed by one or more processing units, cause the one or more processing units to perform operations including receiving a configuration including a simulated request for executing a task, the task associated with at least one of a vehicle simulation of a vehicle operation or a vehicle software build; executing a simulation of operations of a scheduler and task execution, where the executing includes estimating a runtime for the task based on at least one of a driving scenario associated with the task or a vehicle compute framework associated with the task; determining, by the scheduler, a schedule for executing the task based at least in part on the estimated runtime; and executing, based on the determined schedule, the task using a task run model; and calculating a metric for the scheduler based on an output of the simulation.

In Example 20, the one or more non-transitory, computer-readable media of example 19 can optionally include where the determining the schedule is further based on whether the task is associated with a first task category or a second task category, the vehicle simulation is in the first task category, and the vehicle software build is in the second task category.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure. Claim language reciting “at least one of” a set indicates that one member of the set or multiple members of the set satisfy the claim.

1. A computer-implemented system, comprising:
one or more processing units; and
one or more non-transitory computer-readable media storing instructions, when executed by the one or more processing units, cause the one or more processing units to perform operations comprising:
receiving a configuration including a simulated request for executing a task associated with at least one of a vehicle software build or a vehicle simulation of a vehicle;
executing a simulation of operations of a scheduler and task execution, wherein the executing comprises:
determining, by the scheduler, a schedule for executing the task based on the configuration and at least one of a driving scenario or a vehicle compute framework associated with the task; and
executing, based on the determined schedule, the task using a task run model; and
calculating a metric for the scheduler based on an output of the simulation.

2. The computer-implemented system of claim 1, wherein the determining the schedule comprises:
estimating a runtime for the task based on the driving scenario.

3. The computer-implemented system of claim 2, wherein the driving scenario includes information associated with at least one of a road condition, a city, a weather condition, or a road asset.

4. The computer-implemented system of claim 1, wherein the determining the schedule comprises:
estimating a runtime for the task based on the vehicle compute framework.

5. The computer-implemented system of claim 4, wherein the vehicle compute framework is one of a perception compute framework, a prediction compute framework, a planning compute framework, or a driving scenario replay framework.

6. The computer-implemented system of claim 1, wherein:
the determining the schedule is further based on whether the task is associated with a first task category or a second task category,
the vehicle simulation is in the first task category, and
the vehicle software build is in the second task category.

7. The computer-implemented system of claim 1, wherein the configuration further includes an indication of at least one of a queue size or a number of pending tasks associated with a queue state model.

8. The computer-implemented system of claim 1, wherein the configuration further includes an indication of at least one of a compute resource capacity, a storage resource capacity, or a network resource capacity for a hardware platform associated with a resource availability model.

9. The computer-implemented system of claim 1, wherein the configuration further includes an indication of at least one of a compute resource occupancy, a storage resource occupancy, or a network resource occupancy for a hardware platform associated with a resource availability model.

10. The computer-implemented system of claim 1, wherein the configuration further includes an indication of at least one of a priority, a runtime, a task completion goal, a file uploading time duration, or a file downloading time duration associated with the task.

11. The computer-implemented system of claim 1, wherein the executing the simulation further comprises:
validating at least one of a task start time, a task runtime, or a task completion time against a predefined condition.

12. The computer-implemented system of claim 1, wherein the calculating the metric for the scheduler is based on a comparison between a completion time of the task and a completion goal for the task.

13. The computer-implemented system of claim 1, wherein the calculating the metric for the scheduler is based on an ordering of tasks scheduled by the scheduler.

14. The computer-implemented system of claim 1, wherein the calculating the metric for the scheduler is based on priorities of tasks executed over a certain time duration.

15. A computer-implemented method, the method comprising:
receiving a configuration including a simulated request for executing a task, the task associated with at least one of a vehicle simulation of a vehicle operation or a vehicle software build;
executing a simulation of operations of a scheduler and task execution, wherein the executing comprises:
determining, by the scheduler, a schedule for executing the task based on the configuration and at least one of a driving scenario or a vehicle compute framework associated with the task; and
executing, based on the determined schedule, the task using a task run model; and
calculating a metric for the scheduler based on an output of the simulation.

16. The computer-implemented method of claim 15, wherein:
the determining the schedule comprises:
estimating a runtime for the task based on a driving scenario associated with the task, and
the driving scenario includes information associated with at least one of a road condition, a city, a weather condition, or a road asset.

17. The computer-implemented method of claim 15, wherein:
the determining the schedule comprises:
estimating a runtime for the task based on a vehicle compute framework associated with the task, and
the vehicle compute framework is one of a perception compute framework, a prediction compute framework, a planning compute framework, or a driving scenario replay framework.

18. The computer-implemented method of claim 15, wherein:
the determining the schedule is further based on whether the task is associated with a first task category or a second task category,
the vehicle simulation is in the first task category, and
the vehicle software build is in the second task category.

19. One or more non-transitory, computer-readable media encoded with instructions that, when executed by one or more processing units, cause the one or more processing units to perform operations comprising:
receiving a configuration including a simulated request for executing a task, the task associated with at least one of a vehicle simulation of a vehicle operation or a vehicle software build;
executing a simulation of operations of a scheduler and task execution, wherein the executing comprises:
estimating a runtime for the task based on at least one of a driving scenario associated with the task or a vehicle compute framework associated with the task;
determining, by the scheduler, a schedule for executing the task based at least in part on the estimated runtime; and
executing, based on the determined schedule, the task using a task run model; and
calculating a metric for the scheduler based on an output of the simulation.

20. The one or more non-transitory, computer-readable media of claim 19, wherein:
the determining the schedule is further based on whether the task is associated with a first task category or a second task category,
the vehicle simulation is in the first task category, and
the vehicle software build is in the second task category.
